(19) United States
(12) Patent Application Publication
(10) Pub. No.: US 2010/0075510 A1
(43) Pub. Date: Mar. 25, 2010

(54) Method for Pulsed plasma deposition of titanium dioxide film

(76) Inventors: Der-Jun JAN, Longtan Township (TW); Chi-Fong Ai, Longtan Township (TW)

Correspondence Address: SINORICA, LLC, 2275 Research Blvd., Suite 500, ROCKVILLE, MD, 20850, US

(21) Appl. No.: 12/237,902

(22) Filed: Sep. 25, 2008

(51) Int. Cl. H01L 21/31

(52) U.S. Cl. 438/785; 257/E21.085

(57) ABSTRACT

A method for pulsed plasma deposition of titanium dioxide film is revealed. The method includes the steps of: (1) set a substrate into a chamber and the chamber is pumped down to a certain vacuum level. (2) Introduce titanium tetraisopropoxide gas and gas containing oxygen into the chamber and a RF (radio frequency) pulse power supply is turned on to create a glow discharge for generating pulsed plasma. (3) A layer of titanium dioxide film is deposited on the substrate by the pulsed plasma. The TiO₂ film is deposited on a substrate such as plastic substrate at low temperature according to the method so that the heat-resistant and conductive requirements of conventional substrates are removed.

### BACKGROUND OF THE INVENTION

1. Field of Invention

The present invention relates to a method for pulsed plasma deposition of titanium dioxide film, especially to a method for deposition of titanium dioxide film by means of pulsed plasma that is applied to various fields such as microelectronic materials and photocatalytic materials.

2. Description of Related Art

Generally, titanium dioxide (TiO₂) film is used as optical multi-layer film due to its high refractive index within visible light range. The refractive index is over 2.3. Moreover, the TiO₂ features on high dielectric constant, chemical stability, thermal stability and semiconductor characteristic so that it is applied to microelectronic and photocatalytic materials. A common way for deposition of titanium dioxide film is Physical Vapor Deposition (PVD), such as electron-beam evaporation and magnetron sputtering. In the PVD method, the average energy per deposited atom is quite low so that additional energy is required while depositing. For example, an-ion beam for Ion Beam Assisted Deposition is applied, the temperature of the substrate is increased, or post-deposition annealing is employed. However, these ways can not be applied to plastic substrate.

Plasma Enhanced Chemical Vapor Deposition (PECVD) uses electrical energy to create a glow discharge in which gas molecules are ionized into reactive free radicals and high energy ions so that temperature for depositing thin films is effectively reduced. While depositing TiO₂ films by PECVD, a common precursor is titanium tetraisopropoxide (TTIP) that is an organic compound containing titanium and is liquid at room temperature. In use, the TTIP is heated to form vapor and set in an oxygen atmosphere. The mixture of TTIP and oxygen is introduced into a vacuum chamber. The plasma is generated by direct current (DC) discharge or radio frequency (RF) and is deposited on a substrate. For example, refer to Nakamura etc., J. Mater. Res., 16(2), 621-626(2001), oxygen gas is introduced into a Multi-jet plasma source to create oxygen plasma reacting with TTIP for forming a titanium dioxide film on a substrate surface. In order to make oxygen ions react completely with TTIP, the substrate temperature is as high as 300 degrees Celsius. As a prior art disclosed in Cruz etc., Surf. Coat. Technol., 126(2-3): 123-130(2000), plasma of TTIP and oxygen/argon is created by RF(13.56 MHz). A substrate is set beside grounded electrodes and ions are directed into the substrate by DC (direct current) bias voltage. Due to applying of the bias voltage, the substrate should be a conductor.

Refer to conventional techniques available, there is no one related to pulsed plasma deposition of TiO₂ film. Moreover, the substrate used in traditional techniques requires heat resistance and conductivity. Thus there is a need to provide a method for pulsed plasma deposition of titanium dioxide film in which the TiO₂ film is deposited on a substrate such as plastic substrate at low temperature for removal of the heat-resistant and conductive requirements of the substrate.

### SUMMARY OF THE INVENTION

Therefore it is a primary object of the present invention to provide a method for pulsed plasma deposition of titanium dioxide film in which the TiO₂ film is deposited on a substrate such as plastic substrate at low temperature so that the heat-resistant and conductive requirements of the substrate are removed.

It is another object of the present invention to provide a method for pulsed plasma deposition of titanium dioxide film that deposits the TiO₂ film on a substrate by pulsed plasma. This is a novel deposition way of titanium dioxide film.

In order to achieve above objects, the present invention provide a method for pulsed plasma deposition of titanium dioxide film formed by following steps. Firstly, set a substrate into a chamber and the chamber is pumped down to a certain vacuum level. Then introduce titanium tetraisopropoxide gas and gas containing oxygen into the chamber and a RF (radio frequency) pulse power supply is turned on to create a glow discharge for generating pulsed plasma. Thus a layer of titanium dioxide film is deposited on the substrate by the pulsed plasma.

### BRIEF DESCRIPTION OF THE DRAWINGS

The structure and the technical means adopted by the present invention to achieve the above and other objects can be best understood by referring to the following detailed descriptions of the preferred embodiments and the accompanying drawings, wherein

FIG. 1 is a schematic drawing showing structure of an embodiment of a PECVD device according to the present invention;

FIG. 2 is a flow chart showing steps of a method for pulsed plasma deposition of titanium dioxide film according to the present invention;

FIG. 3 is a schematic drawing showing structure of an embodiment of a hollow cathode PECVD device according to the present invention;

FIG. 4 shows relationship between optical constants and wavelength of TiO₂ film;

FIG. 5 shows XPS(X-ray photoelectron spectroscopy) depth profile analysis of TiO₂ film;

FIG. 6 is a schematic drawing showing structure of an embodiment of a helicon plasma deposition device according to the present invention;

FIG. 7 shows relationship between optical constants and wavelength of TiO₂ film.

### DETAILED DESCRIPTION OF THE PREFERRED EMBODIMENT

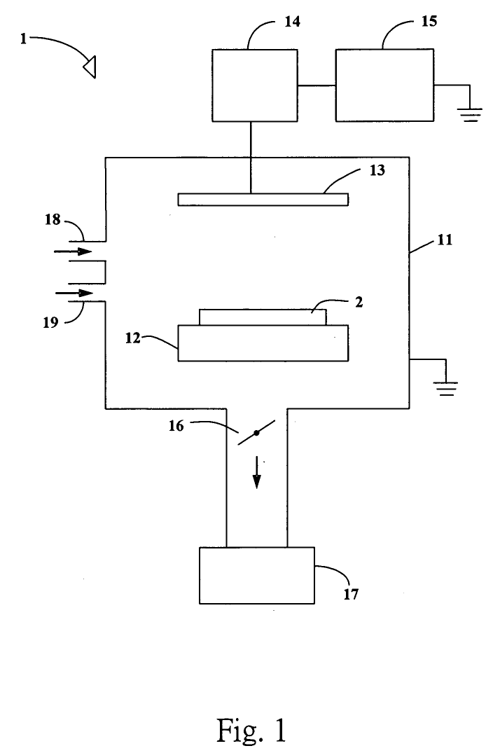

Refer to FIG. 1, a typical PECVD apparatus 1 used in an embodiment of the present invention consists of a chamber 11, a substrate holder 12 arranged inside the chamber 11, a negative electrode 13 disposed in the chamber 11, an impedance-matcher 14 connected with the negative electrode 13, a RF (radio frequency) pulse power supply 15 connected with the impedance-matcher 14, a pneumatic control valve 16 arranged on a bottom of the chamber 11, a pump system 17 located under the 16, and two gas pipelines 18, 19 disposed on one side of the chamber 11.

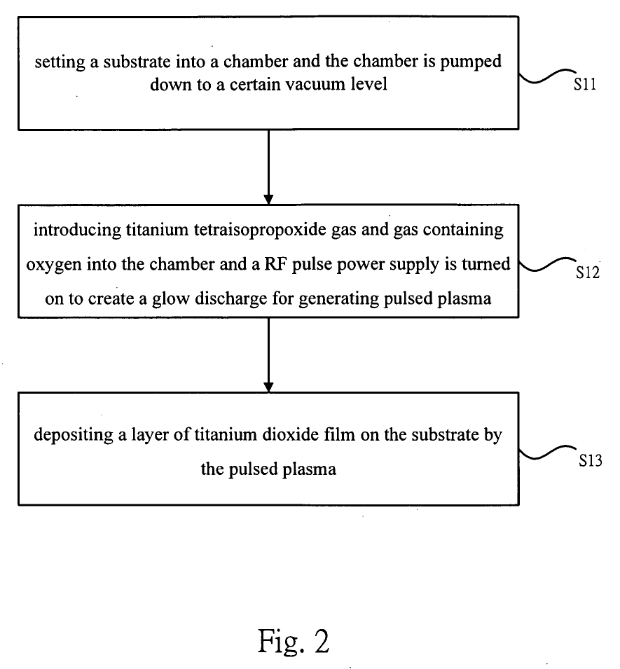

A method for pulsed plasma deposition of titanium dioxide film according to the present invention includes the following steps, as shown in FIG. 1 & FIG. 2:
(1) To set a substrate 2 into a chamber 11 and the chamber 11 is pumped down to a certain vacuum level.
(2) Then introduce titanium tetraisopropoxide gas and gas containing oxygen into the chamber 11 and a RF (radio frequency) pulse power supply 15 is turned on to create a glow discharge for generating pulsed plasma; and
(3) A layer of titanium dioxide film is deposited on the substrate 2 by the pulsed plasma.

The vacuum is under 10⁻³ torr. The substrate holder 12 and the negative electrode 13 are cooled down by introduction of cooling water for absorbing heat energy from plasma discharge. Thus the temperature of the substrate 2 (can be a plastic substrate) is decreased. The titanium tetraisopropoxide gas mixed with argon gas and the gas containing oxygen can be introduced into the chamber 11 respectively by the gas pipeline 18 and the gas pipeline 19, or mixed with each other outside the chamber 11 and then being introduced into the chamber 11. As to the pneumatic control valve 16, it is used to maintain air pressure at 10⁻³˜10⁻¹ torr. Then the RF (radio frequency) pulse power supply 15 is turned on for providing alternating current. Through impedance modification of the impedance-matcher 14, a pulsed plasma is generated. Working frequency of the RF pulse power supply 15 ranges from 1 MHz-100 MHz, pulse frequency is from 1 Hz to 3 K Hz, and pulse duty cycle is 1%-60%. By means of the pulsed plasma, the TiO₂ film is deposited on surface of the substrate. The power supply is not turned off until the required thickness of the film is achieved. The gas containing oxygen is selected from one of the followings: oxygen (O₂), nitrous oxide (N₂O) and carbon dioxide (CO₂). The substrate 2 is set inside a plasma glow region or an afterglow region of the pulsed plasma. The TTIP is introduced into the plasma glow region or the afterglow region.

### Embodiment One

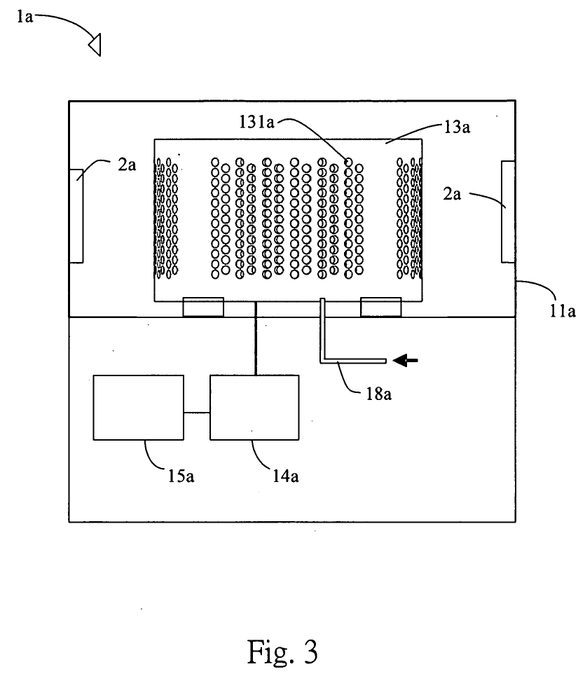

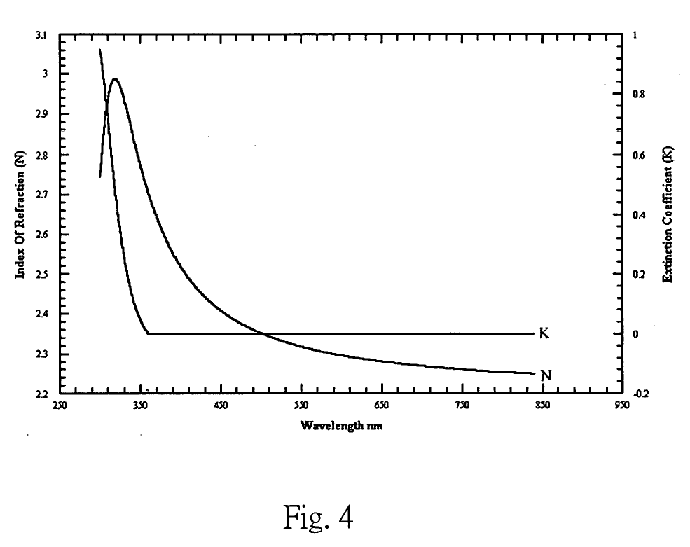

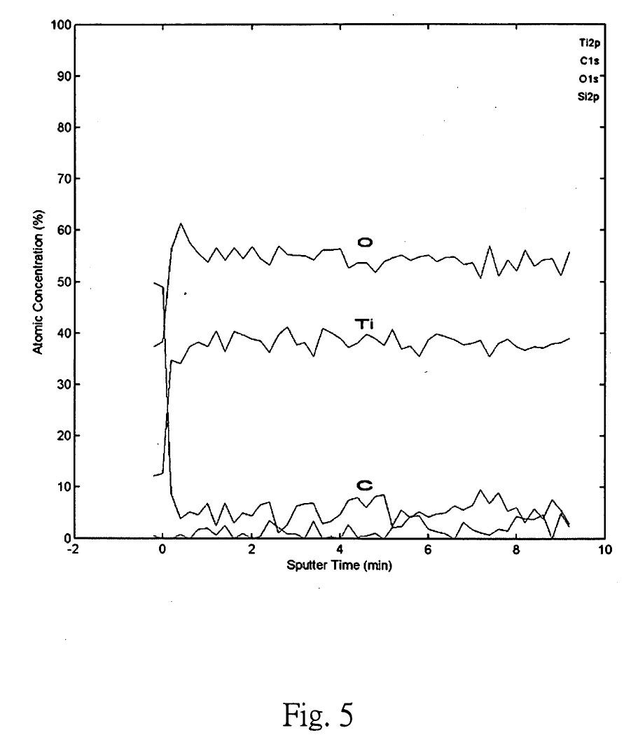

Refer to FIG. 3, a hollow cathode PECVD apparatus 1a is used in this embodiment. The negative electrode is a cylindrical negative electrode 13a with a plurality of round holes 131a, in which the ratio of diameter of an opening of the hole to the depth is 1:3. There is a pore on a bottom of the hole 131a so as to release the reacted gas. After the negative electrode 13a being connected with a RF (radio frequency) pulse power supply 15a, high-density plasma is generated in the hole 131a. In this embodiment, a substrate 2a is put into a chamber 11a and then the chamber is pumped down to a certain vacuum level (<10⁻³ torr). A metal can with liquid TTIP is heated to 50° C. and 20 sccm Argon gas is introduced in as carrier gas. After being mixed with 80 sccm N₂O, the gas mixture passes through a pipeline 18a into the cylindrical negative electrode 13a in the chamber 11a to create a glow discharge for generating pulsed plasma. The titanium dioxide (TiO₂) film is deposited on the substrate 2 by the pulsed plasma. The silicon substrate 2a is put on a wall of the chamber 11a and the distance between the opening of the hole 131a and the silicon substrate 2a is 3 cm. During deposition processes, there is no need to heat the silicon substrate 2a. By the RF pulse power supply 15a with various pulse frequency, duty cycle and RF pulse power, the TiO₂ film is deposited, as shown in table 1. When required thickness of the film is achieved, the RF pulse power supply 15a is turned off and the silicon substrate 2a is taken out. A metrology systems for thin-film material characterization (Film Tek2000, SCI, US) is used to measure optical properties of the film. The results are shown in table 1 and FIG. 4. The XRD (X-ray diffraction) result reveals that the film is amorphous. FIG. 5 is XPS (X-ray photoelectron spectroscopy) depth profile analysis of the deposited film. The film is TiO₂ and the elements are distributed uniformly.

TABLE 1
optical constants at wavelength of 550 nm of TiO₂ film formed
under different conditions:

| | | | RF pulse | refraction | extinction |
|---|---|---|---|---|---|
| | pulse | | power | index at | coefficient at |
| | frequency | duty cycle | supply | wavelength of | wavelength |
| order | (Hz) | (%) | (W) | 550 nm | of 550 nm |
| 1 | 1 | 10 | 300 | 2.365 | 0 |
| 2 | 5 | 10 | 300 | 2.296 | 7.7 × 10⁻⁵ |
| 3 | 10 | 5 | 300 | 2.037 | 8.3 × 10⁻⁵ |

### Embodiment Two

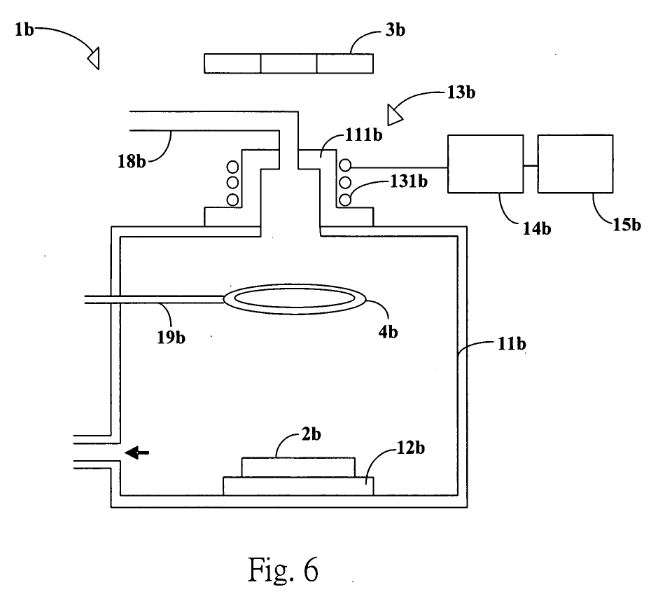

The plasma source in this embodiment is permanent magnet helicon plasma source, referred to F. F. Chen and H. Torreblanca, Plasma Phys. Control. Fusion. 49, A81-A93 (2007) for related details. As shown in FIG. 6, a helicon plasma deposition apparatus 1b is disclosed. The device 1b includes a permanent magnet helicon plasma source 13b, a diffusion chamber 11b, a permanent magnet 3b, and induction coil 131a. After connecting with a RF (radio frequency) pulse power supply 15b, plasma is generated in a quartz glass tube 111b of the diffusion chamber 11b.

The process in this embodiment includes following steps:

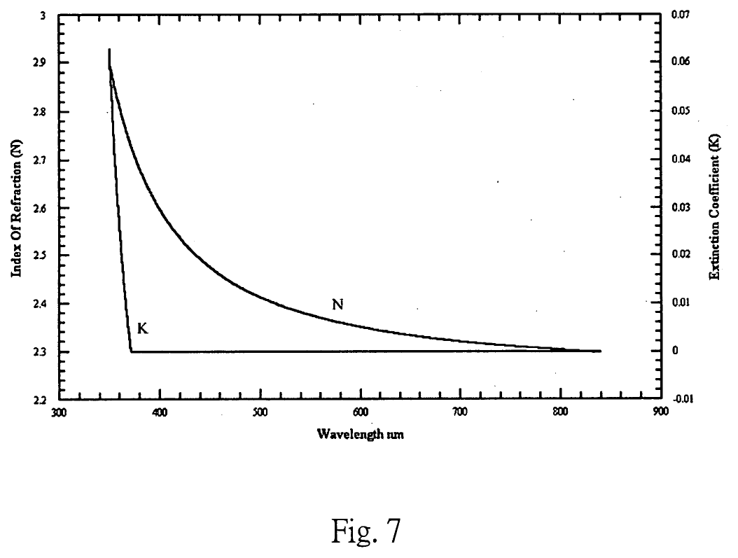

Set a silicon wafer 2b on a stage 12b of the diffusion chamber 11b and the diffusion chamber 11b is pumped down to vacuum. The stage 12b is introduced with cold water for cooling down. After achieving the required vacuum level (<10⁻³ torr), N₂O of 80 sccm is introduced through a pipeline 18b into the quartz glass tube 111b of the diffusion chamber 11b. Then turn on the RF pulse power supply 15b to generated oxygen pulsed plasma diffused into the diffusion chamber 11b. The mixture of TTIP and carrier gas Ar is introduced into a gas distribution ring 4b in the diffusion chamber 11b through a pipeline 19b and is reacting with oxygen pulsed plasma to generate pulsed plasma for depositing TiO₂ film on the silicon wafer 2b. The operation parameters in this embodiment are shown in table 2. After the film achieving required thickness, the power supply is turned off. The silicon wafer 2 is taken out and optical parameters of the deposited TiO₂ film are measured. The results are shown in table 2. FIG. 7 shows relationship between optical constants and wavelength of TiO₂ film.

TABLE 2
optical constants at wavelength of 550 nm of TiO₂ film formed
under different conditions:

| | | | RF pulse | refraction | extinction |
|---|---|---|---|---|---|
| | pulse | | power | index at | coefficient |
| | frequency | duty cycle | supply | wavelength | at wavelength |
| order | (Hz) | (%) | (W) | of 550 nm | of 550 nm |
| 1 | 1 | 50 | 600 | 2.346 | 0 |
| 2 | 1 | 50 | 400 | 2.158 | 0 |
| 3 | 1000 | 50 | 300 | 2.206 | 0.021 |

In summary, the present invention provides a method for pulsed plasma deposition of titanium dioxide film in which the TiO₂ film is deposited on a substrate such as plastic substrate at low temperature so that the substrate doesn't require have heat-resistance and conductivity.

Additional advantages and modifications will readily occur to those skilled in the art. Therefore, the invention in its broader aspects is not limited to the specific details, and representative apparatus shown and described herein. Accordingly, various modifications may be made without departing from the spirit or scope of the general inventive concept as defined by the appended claims and their equivalents.

1. A method for pulsed plasma deposition of titanium dioxide film comprising the steps of:
(1) setting a substrate into a chamber and the chamber is pumped down to a certain vacuum level;
(2) introducing titanium tetraisopropoxide and gas containing oxygen into the chamber and turning on a RF (radio frequency) pulse power supply to create a glow discharge for generating pulsed plasma, wherein the gas containing oxygen is oxygen gas(O2), nitrous oxide (N2O) or carbon dioxide (CO2); and
(3) depositing a layer of titanium dioxide film on the substrate by the pulsed plasma.

2. The method as claimed in claim 1, wherein in the step (1), the substrate is a plastic substrate.

3. The method as claimed in claim 1, wherein in the step (1), the vacuum level is under 10−3 torr.

4. The method as claimed in claim 1, wherein in the step (1), the substrate is further set on a substrate holder that is cooled down by cooling water.

5. The method as claimed in claim 1, wherein in the step (2), the titanium tetraisopropoxide gas and the gas containing oxygen are introduced into the chamber separately.

6. The method as claimed in claim 1, wherein in the step (2), the titanium tetraisopropoxide gas and gas containing oxygen are mixed in advance and before the step (2).

7. The method as claimed in claim 1, comprising a step of: mixing the titanium tetraisopropoxide gas with argon gas in advance before the step (2).

8. The method as claimed in claim 1, wherein the step (2) further comprising a step of: generating oxygen pulsed plasma firstly and then the oxygen pulsed plasma reacting with the titanium tetraisopropoxide gas to generate the pulsed plasma.

9. The method as claimed in claim 1, wherein in the step (2), the RF pulse power supply is connected with a negative electrode.

10. The method as claimed in claim 1, wherein in the step (2), pulse frequency of the RF pulse power supply ranges from 1 Hz to 3 KHz.

11. The method as claimed in claim 1, wherein in the step (2), a pulse duty cycle of the RF pulse power supply ranges from 1% to 60%.

12. (canceled)

13. The method as claimed in claim 1, wherein the substrate is set inside a plasma glow region of the pulsed plasma.

14. The method as claimed in claim 1, wherein the substrate is set inside an afterglow region of the pulsed plasma.

15. The method as claimed in claim 1, wherein the titanium tetraisopropoxide is introduced into a plasma glow region of the pulsed plasma.

16. The method as claimed in claim 1, wherein the titanium tetraisopropoxide is introduced into an afterglow region of the pulsed plasma.
